(19) United States
(12) Patent Application Publication
(10) Pub. No.: US 2024/0412973 A1
(43) Pub. Date: Dec. 12, 2024

(54) PATTERNING USING MONOMER BASED SACRIFICIAL MATERIAL LIFTOFF

(71) Applicant: BAE SYSTEMS Information and Electronic Systems Integration Inc., Nashua, NH (US)

(72) Inventors: Nathaniel P. Wyckoff, Marion, IA (US); Benjamin Terry, Cedar Rapids, IA (US); Alexander S. Warren, North Liberty, IA (US)

(73) Assignee: BAE SYSTEMS Information and Electronic Systems Integration Inc., Nashua, NH (US)

(21) Appl. No.: 18/206,325

(22) Filed: Jun. 6, 2023

(51) Int. Cl. H01L 21/027; H01L 21/02

(52) U.S. Cl. CPC H01L 21/0272; H01L 21/02513; H01L 21/0259; H01L 21/02631

(57) ABSTRACT

A method includes forming a plurality of islands of first material on a plurality of first sections of a layer. A plurality of second sections of the layer are not covered by the first material. The method further includes depositing a second material on (i) the islands of first material and (ii) the second sections of the layer that are not covered by the islands of first material. The method further includes evaporating and/or sublimating the islands of first material and removing remnants of the second material that were on the islands of the first material. In an example, the second material remains on the second sections of the layer, to thereby form a pattern of the second material on the layer. In an example, the first material is a monomer, and the second material is a conductor or a dielectric or a semiconductor.

### TECHNICAL FIELD

The present disclosure relates generally to microelectronic devices, and more specifically to patterning a material on a layer within a microelectronic device.

### BACKGROUND

An integrated circuit structure includes a plurality of components, such as transistors, diodes, conductive lines, vias, and/or passive devices such as resistors, inductors, and capacitors. In an example, the integrated circuit structure may comprise a plurality of layers, where each layer may comprise a dielectric material or a conductive material, or both. One or more corresponding components may be formed on or in a layer. To form components on or in a layer, one or more materials may be patterned on a layer (e.g., to form pre-specified patterns of the materials on the layer), where the patterned materials may include a dielectric material and/or a conductive material.

### BRIEF DESCRIPTION OF THE DRAWINGS

FIG. 1A illustrate a flowchart depicting a method for forming a plurality of islands of sacrificial material on a plurality of first sections of a layer, wherein a plurality of second sections of the layer are not covered by the sacrificial material, in accordance with an embodiment of the present disclosure.

FIG. 1B illustrate a flowchart depicting another method for forming a plurality of islands of sacrificial material on a plurality of first sections of a layer, wherein a plurality of second sections of the layer are not covered by the sacrificial material, in accordance with an embodiment of the present disclosure.

FIGS. 2A and 2B collectively illustrate an example integrated circuit structure in various stages of processing in accordance with the methodology of FIG. 1A, in accordance with an embodiment of the present disclosure.

FIGS. 3A, 3B, and 3C collectively illustrate an example integrated circuit structure in various stages of processing in accordance with the methodology of FIG. 1B, in accordance with an embodiment of the present disclosure.

FIG. 4 illustrate a flowchart depicting a method for forming an integrated circuit structure in which a material is on a plurality of sections of a layer, to thereby form a pattern of the material on the layer, in accordance with an embodiment of the present disclosure.

FIGS. 5A1, 5A2, 5B1, 5B2, 5C1, and 5C2 collectively illustrate an example integrated circuit structure in various stages of processing in accordance with the methodology of FIG. 4, in accordance with an embodiment of the present disclosure.

The figures depict various embodiments of the present disclosure for purposes of illustration only and are not necessarily drawn to scale. Numerous variations, configurations, and other embodiments will be apparent from the following detailed discussion.

### DETAILED DESCRIPTION

Disclosed herein are techniques for patterning a material on a layer, where the patterning process is substantially free of chemical etchants, and is based on a physical change of a sacrificial material. Examples of the physical changes of the sacrificial material include melting, evaporation, and/or sublimation of the sacrificial material, which avoids or otherwise reduces the use of harsh chemical etchants or photolithography. In one example, a monomer may be used as the sacrificial material, although other materials may also be used. The patterning process is relatively gentle on the material and/or the layer (e.g., compared to a case where chemical etchants are used), with no or reduced possibilities of chemical incompatibility during the patterning process.

In one embodiment, the patterning process involves forming a plurality of islands of sacrificial material on a plurality of first sections of a layer, where a plurality of second sections of the layer are not covered by the sacrificial material. In an example, the sacrificial material is a monomer. In one example, the plurality of islands of the sacrificial material may be formed by initially blanket depositing the sacrificial material on the layer, and using laser ablation to pattern the sacrificial material and form the islands of the sacrificial material on the layer. In another example, the plurality of islands of the sacrificial material may be formed by depositing the sacrificial material on the layer through a mask, such as a shadow mask.

After the plurality of islands of the sacrificial material are formed on the plurality of first sections of the layer, a material is deposited on (i) the plurality of islands of sacrificial material and (ii) the plurality of second sections of the layer that are not covered by the plurality of islands of sacrificial material. Subsequently, a physical change is caused to the sacrificial material. For example, the plurality of islands of sacrificial material is evaporated (where the solid sacrificial material initially melts and transforms into a liquid state, and then transforms to a gaseous state through evaporation) and/or sublimated (where the solid sacrificial material transforms into gaseous state directly, by bypassing a liquid state) and any material on the plurality of islands of the sacrificial material is accordingly also removed. Thus, a pattern of the material is formed on the layer. Numerous variations and embodiments will be apparent in light of the present disclosure.

### General Overview

Patterning a material on a layer generally involves a photolithography process and/or chemical etchants to selectively etch the material from above the layer. However, use of chemical etchants may be relatively harsh on the material to be patterned and/or the layer itself, with an increased possibility of chemical incompatibility during the patterning process.

Accordingly, techniques are described herein to pattern a material on a layer, with little or no use of chemical etchants or a photolithography process. In an example, the patterning process is based on one or more physical changes, and consequent removal, of a sacrificial material. In some examples, the sacrificial material is a monomer, although other sacrificial materials may also be used which can be selectively removed. In some such examples, the physical changes of the sacrificial material comprise melting and evaporation, and/or sublimation of the sacrificial material. The patterning process is relatively gentle on the material and/or the layer (e.g., compared to a case where chemical etchants are used), with no or reduced possibilities of chemical incompatibility during the patterning process.

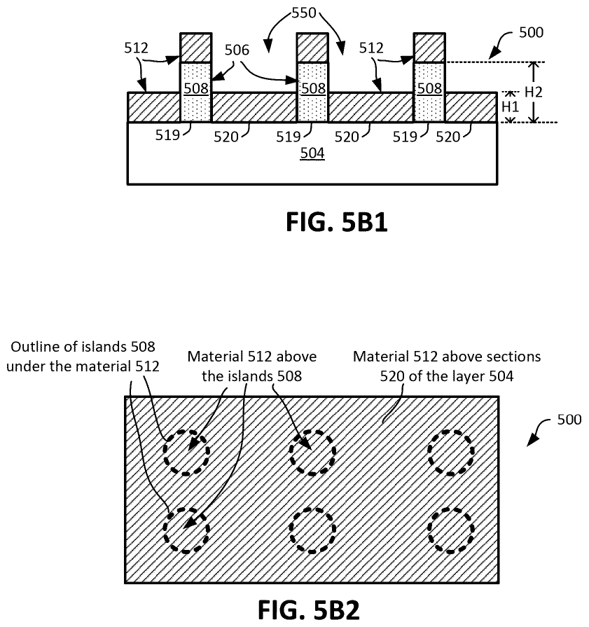

Using a monomer as the sacrificial material is advantageous because, for example, the monomer can later be removed relatively easily and selectively (e.g., through one or more physical processes such as melting and evaporation, and/or sublimation). A monomer is generally a short chain organic molecule that may react together with one or more other short chain monomer molecules, e.g., to form a relatively large polymer chain or another three-dimensional complex chain. For example, a monomer is a short chain compound, having carbon backbones. In an example, because monomers comprise relatively short chain (e.g., shorter compared to a polymer), and because the chains are not covalently bonded, a monomer is relatively weak chemically (e.g., compared to a polymer). Accordingly, as described below, a monomer removal process is relatively easy. For example, during the sacrificial material removal process described below (e.g., in FIG. 4), the monomer can be removed through physical changes (such as melting and evaporation, and/or sublimation) of the monomer, e.g., without using any harsh chemical or wet etch process for removal of the monomer. Because of the relatively low temperature used to melt, evaporate, and/or sublimate the monomer (e.g., compared to polymers) and because no substantial amount of chemical or etchant is used for removal of the monomer, the monomer removal process is gentle on a layer and/or a material to be patterned on the layer. Furthermore, the monomer removal process leaves little or no significant monomer remnants, thereby avoiding or reducing changes of contamination due to remnant monomer.

In one embodiment, the patterning process involves initially forming a plurality of islands of the sacrificial material on a plurality of first sections of a layer. In an example, a plurality of second sections of the layer are not covered by the sacrificial material. As described above, in an example, the sacrificial material is a monomer. Any appropriate monomer may be used, such as pyromellitic dianhydride (PMDA), 4,4′-Oxydianiline (ODA), and/or another appropriate monomer.

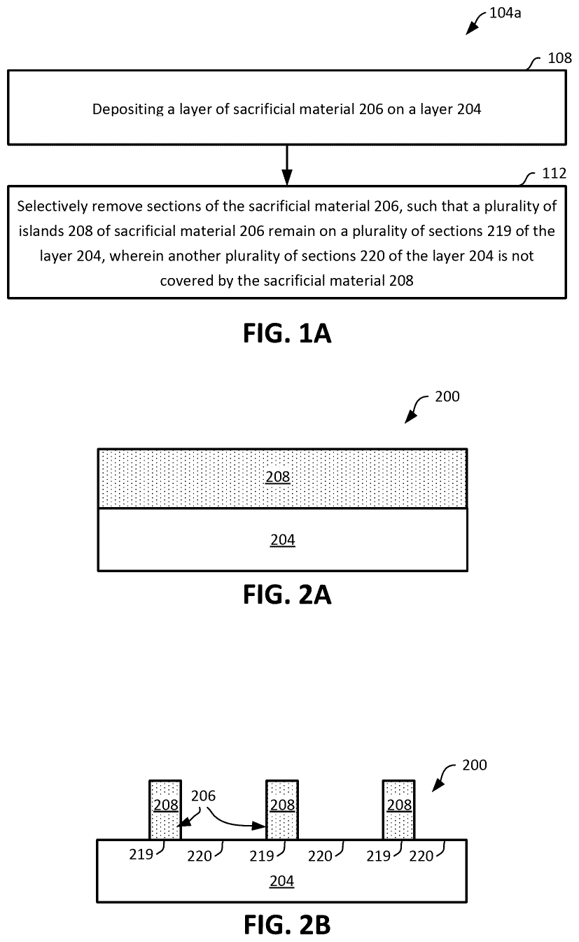

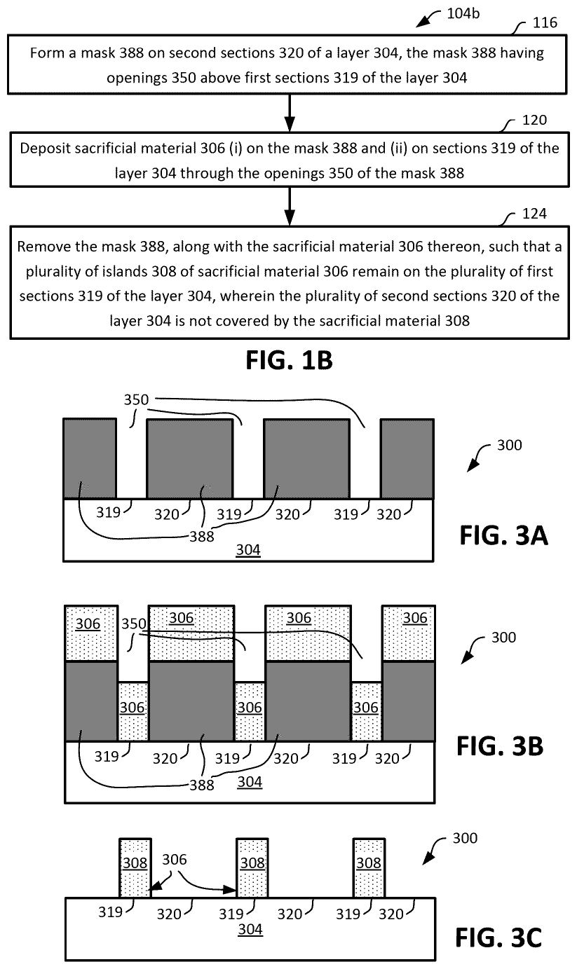

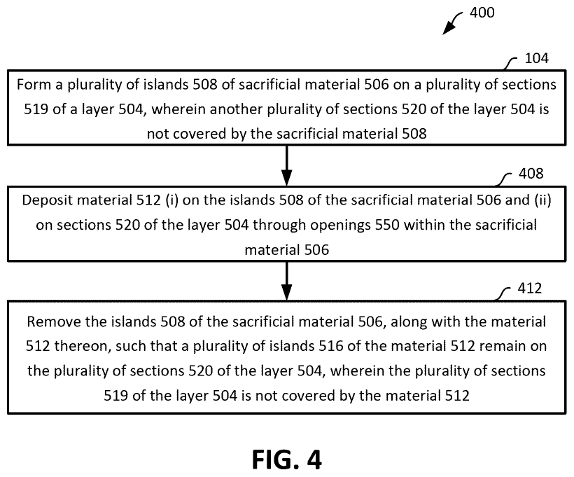

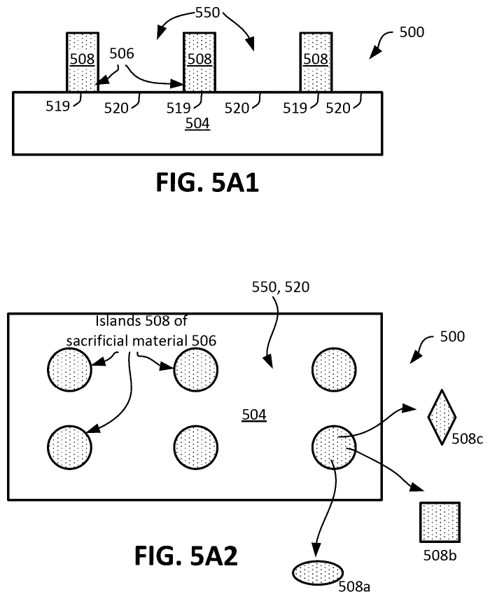

In one example, the plurality of islands of the sacrificial material may be formed by initially blanket depositing the sacrificial material on the layer, and using laser ablation to pattern the sacrificial material and form the islands of the sacrificial material on the layer, e.g., as discussed with respect to FIGS. 1A, 2A, and 2B. In another example, the plurality of islands of the sacrificial material may be formed by depositing the sacrificial material on the layer through a mask, such as a shadow mask, e.g., as discussed with respect to FIGS. 1B, 3A, 3B, and 3C. In an example, laser ablation may be used to generate a relatively higher resolution of the islands of the sacrificial material, e.g., compared to the scenario where the shadow mask is used to form the islands of the sacrificial material.

After the plurality of islands of the sacrificial material are formed on the plurality of first sections of the layer, a material is deposited on (i) the plurality of islands of sacrificial material and (ii) the plurality of second sections of the layer that are not covered by the plurality of islands of sacrificial material. In an example, the material may be deposited as a conformal thin film.

In an example, the material may be deposited in a low pressure chamber such as in at least a partial vacuum environment (although the material may also be deposited at ambient atmospheric pressure in another example), and the sacrificial material (e.g., which may be a monomer, as described above) may be vacuum compatible and stable during deposition of the material at the low pressure or at ambient atmospheric pressure. In an example, the deposited material may be dielectric material, semiconductor material, or conductive material, for example, and may be implementation specific.

Subsequently, in an example, the islands of the sacrificial material are removed from the plurality of first sections of the layer, along with the material thereon, e.g., by causing a physical change to the sacrificial material. As a result of the removal of the sacrificial material and the material thereon, a plurality of islands of the material remain on the plurality of second sections of the layer. Note that the plurality of first sections of the layer (which was previously covered by the sacrificial material) are not covered by the material.

As described above, the islands of the sacrificial material may be removed by causing physical changes to the sacrificial material, such as melting and evaporating, sublimating, and/or burning-out the sacrificial material. The sacrificial material removal process may be a chemical etchant free technique, and may not use a photolithography process. For example, the sacrificial material (e.g., comprising monomer) is removed and the unwanted material on the islands of sacrificial material may be lifted-off by heating the layer and/or the islands of sacrificial material. This results in melting and evaporation, and/or sublimation of the sacrificial material, and lift-off of the material on the islands of sacrificial material.

After the sacrificial material is removed (e.g., through melting, evaporation, sublimination, or otherwise removed), portions of the material that were above the sacrificial material are no longer anchored to the layer. In contrast, other portions of the material on the second sections of the layer are adhered or otherwise anchored to the layer. Accordingly, any remnants of the material that were above the sacrificial material lifts off from the structure along with the sacrificial material. Any remnants of material that may remain above the removed sacrificial material may be removed using, for example, compressed gas or another appropriate cleaning process, given the limited anchoring such remnant material will have. Subsequent to the removal process, a layer of the patterned material remains on the plurality of second sections of the layer (and not on the plurality of first sections of the layer).

In accordance with some embodiments of the present disclosure, these various approaches can be used individually or together to pattern a material on a layer, e.g., using a chemical etchant free patterning process that uses, for example, monomers as sacrificial material. Numerous variations and embodiments will be apparent in light of the present disclosure.

As used in the discussion and claims herein, the term “about” indicates that the value listed may be somewhat altered, as long as the alteration does not result in nonconformance of the process or device. For example, for some elements the term “about” can refer to a variation of ±0.1%, for other elements, the term “about” can refer to a variation of ±1% or ±10%, or any point therein. As also used herein, terms defined in the singular are intended to include those terms defined in the plural and vice versa.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat.

### Methodology

FIG. 1A illustrate a flowchart depicting a method 104a for forming a plurality of islands 208 of sacrificial material 206 on a plurality of first sections 219 of a layer 204, wherein a plurality of second sections 220 of the layer 204 are not covered by the sacrificial material 206, in accordance with an embodiment of the present disclosure. FIGS. 2A and 2B collectively illustrate an example integrated circuit structure 200 in various stages of processing in accordance with the methodology 104a of FIG. 1A, in accordance with an embodiment of the present disclosure. FIGS. 1A, 2A, and 2B will be discussed in unison.

Referring to the method 104a, at 108, a layer of the sacrificial material 206 is deposited on the layer 204. The layer 204 may be an appropriate type of layer on which patterns of a material (e.g., material 506) are to be formed, where formation of the patterns is described with respect to FIG. 4 below. The layer 204 may be a substrate, a layer of dielectric material, a layer of semiconductor material, or a layer of conductive material, for example.

In one embodiment, the sacrificial material 206 may be deposited on the layer 204 using an appropriate deposition technique (e.g., a conformal deposition technique), such as sputtering, chemical vapor deposition (CVD), physical vapor deposition (PVD), atomic layer deposition (ALD), vapor-phase epitaxy (VPE), molecular beam epitaxy (MBE), or liquid-phase epitaxy (LPE), for example. In an example, the layer of the sacrificial material 206 is deposited by an appropriate thermal evaporation technique, e.g., at a temperature of 100-200° C. (or a different temperature range, depending on a type of sacrificial material used).

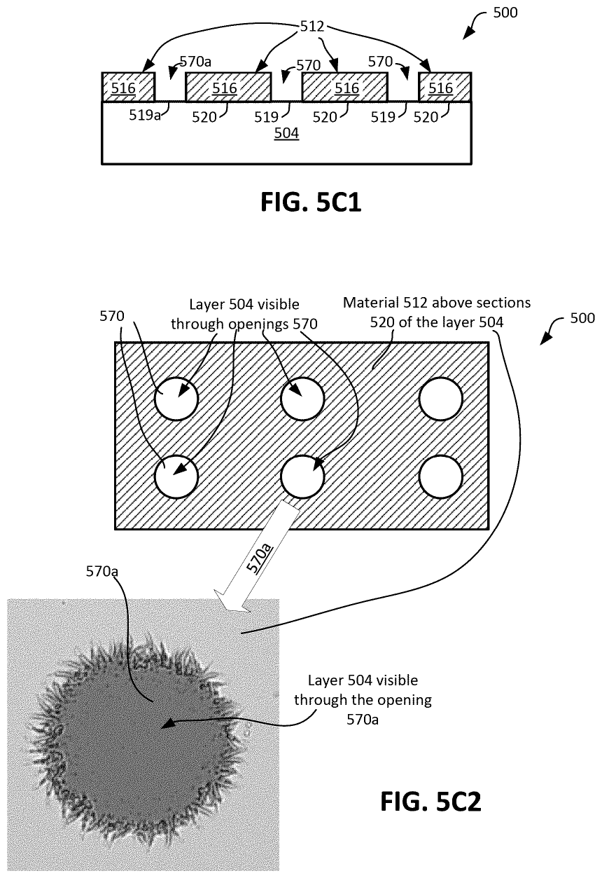

In an example, the layer of the sacrificial material 206 may have a thickness in the range of 10 nanometers (nm) to 50 microns, such as in the subrange of 100 nm to 50 microns, 100 nm to 10 microns, 100 nm to 1 micron, 500 nm to 50 microns, 500 nm to 10 microns, for example, e.g., based on an application (FIG. 5B1 below describes a thickness of a sacrificial layer in further detail).

In one embodiment, the sacrificial material 206 is a monomer, although another type of sacrificial material may also be used. Using a monomer as the sacrificial material 206 is advantageous because, for example, the monomer can later be removed relatively easily (e.g., see process 412 of method 400 of FIG. 4 described below). A monomer is generally a short chain organic molecule that may react together with one or more other short chain monomer molecules, e.g., to form a relatively large polymer chain or another three-dimensional complex chain. For example, a monomer is generally a short chain compound, generally having carbon backbones. In an example, because monomers comprise relatively short chain (e.g., shorter compared to a polymer), and because the chains are not covalently bonded, a monomer is relatively weak chemically (e.g., compared to a polymer). Accordingly, as described below, a monomer removal process is relatively easy. For example, during the sacrificial material removal process described below (e.g., in FIG. 4), the monomer can be removed through one or more physical changes (such as melting and evaporation, and/or sublimation), e.g., without using any harsh chemical or wet etch process for removal of the monomer. Thus, the monomer removal process is a chemical free dry process, for example. Because of the relatively low temperature used to melt, evaporate, and/or sublimate the monomer (e.g., compared to polymers) and because no substantial amount of chemical or etchant is used for removal of the monomer, the monomer removal process is gentle on a layer 504 and/or a material 512 that is to be patterned on the layer, as described below with respect to FIGS. 4, 5A1-5C2. Furthermore, the monomer removal process doesn't leave any significant monomer remnants, thereby avoiding or reducing changes of contamination due to remnant monomer.

Any appropriate type of monomer may be used as the sacrificial material 206. An example monomer that may be used as the sacrificial material 206 is Pyromellitic dianhydride (PMDA, C₆H₂(C₂O₃)₂), which is an organic compound monomer. A boiling point of PMDA monomer is about 397 to 400° C., and may vary based on process conditions (such as air pressure or at least partial vacuum pressure of the reaction chamber). In another example, the organic compound monomer may be sublimated, e.g., transformed from solid to gaseous state directly, by bypassing the liquid state.

Another example monomer that may be used as the sacrificial material 206 is 4,4′-Oxydianiline (ODA, O(C₆H₄NH₂)₂), which is another organic compound monomer. A boiling point of ODA monomer is about 219° C. Any other appropriate type of monomer may also be used for the sacrificial material 206.

The method 104a proceeds from 108 to 112. At 112, sections of the sacrificial material 206 may be selectively removed, such that a plurality of islands 208 of sacrificial material 206 remain on a plurality of first sections 219 of a layer 204, wherein a plurality of second sections 220 of the layer 204 are not covered by the sacrificial material 208, as illustrated in FIG. 2B.

In an example, the selective removal of the sacrificial material 206 is performed using laser ablation or spallation. For example, a laser beam is moved over the sacrificial material 206 using an appropriate technique, e.g., by using a galvo laser beam, where a galvanometer (which is an electromechanical instrument) is used to deflect the laser beam by using a mirror, such that the laser projection is moved in specific pre-configured pattern on the sacrificial material 206. The laser beam selectively removes the sacrificial material 206. Portions of the sacrificial material 206 not removed by the laser beam remain as the islands 208.

Thus, the resultant integrated circuit structure 200 has a plurality of islands 208 of sacrificial material 206 on the plurality of first sections 219 of the layer 204, wherein the plurality of second sections 220 of the layer 204 are not covered by the sacrificial material 208.

Note that the processes in method 104a are shown in a particular order for ease of description. However, one or more of the processes may be performed in a different order or may not be performed at all (and thus be optional), in accordance with some embodiments. Numerous variations on method 104a and the techniques described herein will be apparent in light of this disclosure.

FIG. 1B illustrate another flowchart depicting another method 104b for forming a plurality of islands 308 of sacrificial material 306 on a plurality of first sections 319 of a layer 304, wherein a plurality of second sections 320 of the layer 304 are not covered by the sacrificial material 308, in accordance with an embodiment of the present disclosure. FIGS. 3A, 3B, and 3C collectively illustrate an example integrated circuit structure 300 in various stages of processing in accordance with the methodology 104b of FIG. 1B, in accordance with an embodiment of the present disclosure. FIGS. 1B, 3A, 3B, and 3C will be discussed in unison.

Referring to the method 104b of FIG. 1B, the method 104b comprises, at 116, forming a mask 388 on second sections 320 of a layer 304, where the mask 388 has openings 350 above first sections 319 of the layer 304, e.g., as illustrated in FIG. 3A. In an example, the description of the layer 204 of FIG. 2A also applies to the layer 304 of FIG. 3A. The mask 388 may be any appropriate type of mask, such as a shadow mask or a hard mask. As illustrated in FIG. 3A, the sections 319 of the layer 304 are exposed through the openings 350 within the mask 388.

The method 104b proceeds from 116 to 120. At 120, sacrificial material 306 is deposited (i) on the mask 388 and (ii) on sections 319 of the layer 304 through the openings 350 of the mask 388, as illustrated in FIG. 3B. In one embodiment, the sacrificial material 306 may be deposited using an appropriate deposition technique, such as sputtering, CVD, PVD, ALD, VPE, MBE, or LPE, for example. For example, the layer of the sacrificial material 306 is deposited by an appropriate thermal evaporation and vapor deposition technique, e.g., at a temperature of 100-200° C. (or a different temperature range, depending on a type of sacrificial material used).

In an example, the layer of the sacrificial material 306 may have a thickness in the range of 10 nanometers (nm) to 50 microns, such as in the subrange of 100 nm to 50 microns, 100 nm to 10 microns, 100 nm to 1 micron, 500 nm to 50 microns, 500 nm to 10 microns, for example, e.g., based on an application (FIG. 5Bs below describes the thickness of a sacrificial layer in further detail).

In an example, the description of the sacrificial material 208 of FIG. 2A also applies to the sacrificial material 308 of FIG. 3B. Thus, as described above with respect to FIG. 2A, the sacrificial material 308 may be a monomer.

The method 104b proceeds from 120 to 124. At 124, the mask 388 is removed, along with the sacrificial material 306 thereon. In an example, as a result, a plurality of islands 308 of sacrificial material 306 remain on the plurality of first sections 319 of the layer 304, wherein the plurality of second sections 320 of the layer 304 are not covered by the sacrificial material 308, as illustrated in FIG. 3C.

In an example where the mask 388 is a shadow mask, the shadow mask is lifted off from the layer 304, along with the sacrificial material 306 thereon. In an example where the mask 388 is a hard mask, the hard mask may be etched using any appropriate etching technique, along with removal of the sacrificial material 306 thereon.

Thus, the resultant integrated circuit structure 300 of FIG. 3C has a plurality of islands 308 of sacrificial material 306 on the plurality of first sections 319 of the layer 304, wherein the plurality of second sections 320 of the layer 304 are not covered by the sacrificial material 308.

Note that the processes in method 104b are shown in a particular order for ease of description. However, one or more of the processes may be performed in a different order or may not be performed at all (and thus be optional), in accordance with some embodiments. Numerous variations on method 104b and the techniques described herein will be apparent in light of this disclosure.

Comparing the structure 200 of FIG. 2B and the structure 300 of FIG. 3C, the method 104a of FIG. 1A and the method 104b of FIG. 1B form similar structures 200 and 300, respectively. In one embodiment, a resolution of the islands 208 of the sacrificial material 206 of FIG. 2B may be more than a resolution of the islands 308 of the sacrificial material 306 of FIG. 3C. Similarly, a pitch of the islands 208 of the sacrificial material 206 of FIG. 2B may be less than a pitch of the islands 308 of the sacrificial material 306 of FIG. 3C. Thus, in an example, the laser ablation of the method 104a of FIG. 1A generates better resolution and finer pitch islands 208 of the sacrificial material 206 of FIG. 2B, e.g., compared to those of the islands 308 of the sacrificial material 306 of FIG. 3C.

In an example, any one of the structures 200 or 300 of FIG. 2B or 3C, respectively, may be used for the below described method 400 of FIG. 4. For example, based on a desired resolution and/or pitch of the islands of sacrificial material, one of the structures 200 or 300 of FIG. 2B or 3C may be selected and used for the below described method 400 of FIG. 4.

FIG. 4 illustrate a flowchart depicting a method 400 for forming an integrated circuit structure 500 in which a material 512 is on a plurality of sections 520 of a layer 504, to thereby form a pattern of the material 512 on the layer 504, in accordance with an embodiment of the present disclosure. FIGS. 5A1, 5A2, 5B1, 5B2, 5C1, and 5C2 collectively illustrate an example integrated circuit structure 500 in various stages of processing in accordance with the methodology 400 of FIG. 4, in accordance with an embodiment of the present disclosure. FIGS. 4, 5A1, 5A2, 5B1, 5B2, 5C1, and 5C2 will be discussed in unison.

FIGS. 5A1, 5B1, 5C1 illustrate cross-sectional views of the structure 500. FIG. 5A2 is a top-down or plan view of the structure 500 of FIG. 5A1; FIG. 5B2 is a top-down or plan view of the structure 500 of FIG. 5B1; and FIG. 5C2 is a top-down or plan view of the structure 500 of FIG. 5C1.

Referring to the method 400 of FIG. 4, the method 400 comprises, at 104, forming a plurality of islands 508 of sacrificial material 506 on a plurality of sections 519 of a layer 504, wherein another plurality of sections 520 of the layer 504 are not covered by the sacrificial material 508, e.g., as illustrated in FIGS. 5A1 and 5A2.

Such islands 508 of sacrificial material 506 may be formed either using the method 104a of FIG. 1A, or using the method 104b of FIG. 1B. For example, as described above, based on a desired resolution and/or pitch of the islands of sacrificial material, one of the structure 200 of FIG. 2B or the structure 300 of FIG. 3C (which are respectively formed using the method 104a or 104b of FIG. 1A or 1B) may be selected and used for the process 104 of the method 400 of FIG. 4. Thus, the process 104 of the method 400 may be performed using either the method 104a of FIG. 1A, or the method 104b of FIG. 1B. In FIG. 5A2 and one or more other figures herein, the islands 508 are illustrated to have a circular or oval cross-section, as illustrated in the plan view of FIG. 5A2. However, the islands 508 and/or other features discussed herein may have any other appropriate cross-sectional shape as well. Some other example shapes of an island 508 are illustrated in FIG. 5A2. For example, an island can have an oval shape 508a, a square or rectangular shape 508b, or a rhombus shape 508c, as illustrated in FIG. 5A2.

As illustrated in FIGS. 5A and 5A2, a plurality of openings 550 are formed above the sections 520 of the layer 504 and through the islands 508 of the sacrificial material 506.

In an example, the description of the sacrificial materials 208 and 308 of FIGS. 2A, 3A also applies to the sacrificial material 508 of FIGS. 5A1 and 5A2. Thus, as described above with respect to FIG. 2A, the sacrificial material 508 of FIGS. 5A1 and 5A2 may be a monomer. Similarly, in an example, the description of the layers 204 and 304 of FIGS. 2A, 3A also applies to the layer 504 of FIGS. 5A1 and 5A2.

The method 400 proceeds from 104 to 408. At 408, material 512 is deposited (i) on the islands 508 of the sacrificial material 506 and (ii) on sections 520 of the layer 504 through openings 550 within the sacrificial material 506, e.g., as illustrated in FIGS. 5B1 and 5B2. In one embodiment, the material 512 may be deposited using an appropriate deposition technique, such as sputtering, CVD, PVD, ALD, VPE, MBE, or LPE, for example. In an example, the material 512 may be deposited as a thin film.

In an example, the material 512 may be deposited in a low pressure chamber such as in at least a partial vacuum environment (although the material 512 may also be deposited at ambient atmospheric pressure in another example), and the sacrificial material 506 (e.g., which may be a monomer, as described above) may be vacuum compatible and stable during deposition of the material 512 at low pressure or at ambient atmospheric pressure. In an example, the material 512 may be dielectric material, semiconductor material, or conductive material, for example, and may be implementation specific.

As illustrated in FIG. 5B1, the islands 508 of sacrificial material 506 has a thickness or height of H2, and the layer of material 512 deposited on the layer 504 and the islands 508 has a thickness or height of H1. In an example, the height H2 is substantially greater than H1. For example, H2 is greater than H1 by a factor of at least 1.2 (e.g., H2 is 120% of H1), or 1.4, or 1.8, or 2.0, or 2.5, or 3.0, for example. As illustrated in FIG. 5B1, the thicknesses or heights H1 and H2 are measured in a direction that is substantially perpendicular to a plane of the layer 504. In an example, relatively high aspect ratio islands 516 of the material 512 may be formed, e.g., by appropriately controlling the heights H1 and H2.

In an example, the height H2 greater than H1 ensures a discontinuity between portions of material 512 above the islands 508 and other portions of material 512 above the sections 520. For example, such a discontinuity facilitates lifting off of the portions of material 512 above the islands 508, e.g., during process 412 described below.

The method 400 proceeds from 408 to 412. At 412, the islands 508 of the sacrificial material 506 are removed, along with the material 512 thereon, such that a plurality of islands 516 of the material 512 remain on the plurality of sections 520 of the layer 504, wherein the plurality of sections 519 of the layer 504 are not covered by the material 512, as illustrated in FIGS. 5C1 and 5C2. The sections 519 of the layer 504 not covered by the material 512 are exposed through openings 570 within the material 512.

In one embodiment, the islands 508 of the sacrificial material 506 may be removed through a substantially chemical free technique, or through an etchant free technique, and without using a photolithography process, for example. For example, the islands 508 of the sacrificial material 506 may be removed by causing one or more physical changes, such as melting and evaporation, and/or sublimation, of the sacrificial material 506.

For example, the sacrificial material 506 (e.g., comprising monomer) is removed and the unwanted material 512 on the islands 508 may be lifted-off by heating the layer 504 and/or the structure 500. This results in transformation of the solid sacrificial material 506 into a liquid state through a melting process, and then to a gaseous state through evaporation; or directly from a solid state to a gaseous state through sublimation of the sacrificial material 506, and lift-off of the material 512 on the islands 508. In an example, the melting, evaporation, and/or sublimation can be performed at atmospheric pressure or under at least partial vacuum, e.g., depending on the type of sacrificial material 506 used.

For example, if the sacrificial material 506 is PMDA (described above) and the process is performed at atmospheric pressure, a temperature of about 400° C. may be used for evaporation of the sacrificial material 506. In another example, if the sacrificial material 506 is ODA (also described above) and the process is performed at atmospheric pressure, a temperature of about 219° C. may be used for evaporation of the sacrificial material 506. The evaporation temperature may also depend on the air pressure within the reaction chamber, and the type of the sacrificial material 506 (e.g., a type of monomer used for the sacrificial material 506). In an example, the evaporation temperature may be at most 500° C. Similarly, in an example, the melting and/or sublimation temperature may also depend on process parameters, such as air pressure.

After the sacrificial material 506 is removed through melting, evaporation, and/or sublimation, portions of the material 512 that were above the sacrificial material 506 are no longer anchored to the layer 504. In contrast, other portions of the material 512 on sections 520 are adhered or otherwise anchored to the layer 504. Accordingly, portions of the material 512 that were above the sacrificial material 506 lifts off from the structure 500 along with the sacrificial material 506. Remnants of portions of the material 512, if any, that were above the removed sacrificial material 506 can be removed using compressed gas (e.g., by blowing the compressed gas, such as air, on the structure 500) or another appropriate cleaning process. In an example, the cleaning process to remove the remnants of the material 512 is also free of harsh chemicals typical of etchants.

As described above, in an example, laser ablation process described with respect to FIGS. 1A, 2A-2B may be used to generate a relatively higher resolution of the islands of the sacrificial material, e.g., compared to the scenario where a mask is used to form the islands of the sacrificial material, as described with respect to FIGS. 1B, 3A-3C. FIG. 5C2 illustrates a magnified view of an opening 570a within the material 516, where the opening 570a is above a section 519a of the layer 504 (see FIGS. 5C1 and 5C2 for opening 570a and section 519a), where the opening 570a is formed using an island of sacrificial material 506 that was formed using a mask, in accordance with FIGS. 1B, 3A-3C. In the plan view of FIG. 5C2, the layer 504 is visible through opening 570a. As illustrated, the opening 570a has imperfections, such as several hair-like protrusions or extensions. This is because a corresponding island 508 of the sacrificial material 506 was formed using the mask 306, e.g., as discussed with respect to FIGS. 1B and 3A-3C. Thus, the corresponding island 508 of the sacrificial material 506 was a relatively low resolution island, having similar imperfections, such as the hair-like protrusions or extensions. Resultantly, when the island 508 of the sacrificial material 506 is removed (e.g., process 412 of method 400), the corresponding opening 570a now as the same imperfections, such as the hair-like protrusions or extensions, as illustrated in FIG. 5C2.

As described above, in one embodiment, the sacrificial material 506 is a monomer (although another type of sacrificial material may also be used). Using a monomer as the sacrificial material 206 is advantageous because, for example, the monomer can later be removed relatively easily (e.g., compared to removing a polymer or another type of sacrificial material). Because monomers comprise relatively short chain (e.g., shorter compared to a polymer), and because the chains are not covalently bonded, a monomer is relatively weak chemically (e.g., compared to a polymer). For example, during the sacrificial material removal process 412, the sacrificial material 506 can be melted and evaporated, or sublimated, or otherwise removed, e.g., without using any harsh chemical or wet etch process for removal of the monomer. Thus, the sacrificial material removal process is a chemical free and dry process, and involves physical change (e.g., evaporation) of the sacrificial material 506, for example. Because of the relatively low temperature used to melt, evaporate, and/or sublimation the monomer (e.g., compared to polymers) and because no substantial amount of chemical or etchant is used for removal of the monomer, the sacrificial material removal process is gentle on the layer 504 and/or the material 512 that is patterned on the layer 204. Also, the sacrificial material removal process eliminates or at least reduces incompatibility between the material 512 and any chemical etch process (e.g., as no chemical etch process is used in method 400). Furthermore, the sacrificial material removal process doesn't leave any significant sacrificial material remnants, thereby avoiding or reducing changes of contamination due to any remnant sacrificial material.

Furthermore, in an example, no photolithography process may be employed to form the structure 500 of FIG. 5C, or for removal of the sacrificial material 506. For example, the islands 508 of sacrificial material 506 are formed using either laser ablation for relatively higher resolution features (e.g., FIGS. 1A, 2A, 2B), or using a shadow mask for relatively lower resolution features (e.g., FIGS. 1B, 3A, 3B, 3C), without an use of a photolithography process (or a chemical etching process). Similarly, the sacrificial material 506 is removed at 412 of the method 400 without any use of a photolithography process.

Removal of a sacrificial material, such as a monomer, has been described herein. For example, as described above, a layer of the monomer is deposited (see process 104), and then at appropriate time in the process flow, heated to cause melting and evaporation, and/or sublimation of the monomer (see process 412). In some other examples, two layers of monomers may be deposited. Thus, in some such examples, the sacrificial material 506 may include two distinct and compositionally different layers of monomers, such as a layer of first monomer and a layer of second monomer. The melting, evaporation, and/or sublimation temperature of the two monomers may be different. During the monomer removal process 412, the first monomer having relatively lower melting and boiling temperature (or lower sublimation temperature) is first removed at a relatively low temperature, followed by removal of the second monomer having relatively higher melting and boiling temperature (or higher sublimation temperature). In some other examples, instead of two, there may be more than two layers of different monomers, having different melting and boiling temperatures and/or different sublimation temperature.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

### Further Example Embodiments

The following examples pertain to further embodiments, from which numerous permutations and configurations will be apparent.

Example 1. A method comprising: forming a plurality of islands of first material on a plurality of first sections of a layer, wherein a plurality of second sections of the layer are not covered by the first material; depositing a second material on (i) the plurality of islands of first material and (ii) the plurality of second sections of the layer that are not covered by the plurality of islands of first material; and evaporating and/or sublimating the plurality of islands of first material and removing remnants of the second material that were on the plurality of islands of the first material, such that the second material remains on the plurality of second sections of the layer, to thereby form a pattern of the second material on the layer.

Example 2. The method of example 1, wherein the first material is a monomer.

Example 3. The method of any one of examples 1-2, wherein removing the remnants of the second material that were on the plurality of islands of the first material comprises: removing the remnants of the second material using compressed gas.

Example 4. The method of any one of examples 1-3, wherein forming the plurality of islands of first material on the plurality of first sections of the layer comprises: depositing the first material on the plurality of first sections and the plurality of second sections of the layer; and selectively removing the first material from the plurality of second sections of the layer, such that the first material remains on the plurality of first sections of the layer to thereby form the plurality of islands of first material.

Example 5. The method of example 4, wherein selectively removing the first material from the plurality of second sections of the layer comprises: ablating the first material from the plurality of second sections of the layer, by passing a laser beam on at least portions of the first material that are on the plurality of second sections of the layer.

Example 6. The method of any one of examples 1-5, wherein forming the plurality of islands of first material on the plurality of first sections of the layer comprises: depositing the first material on the layer through a mask, such that the first material is deposited on the plurality of first sections of the layer, without being deposited on the plurality of second sections of the layer; and removing the mask.

Example 7. The method of example 6, wherein the mask is a shadow mask.

Example 8. The method of any one of examples 1-7, wherein evaporating and/or sublimating the plurality of islands of first material comprises evaporating and/or sublimating the plurality of islands of first material at a temperature that is at most 500° C.

Example 9. The method of any one of examples 1-8, wherein evaporating and/or sublimating the plurality of islands of first material comprises evaporating and/or sublimating the plurality of islands of first material under an at least partial vacuum environment.

Example 10. The method of any one of examples 1-9, wherein a thickness of at least one island of the plurality of islands of first material is at least 20% more than a thickness of the second material deposited on at least one of the plurality of second sections of the layer, wherein the thicknesses are measured in a direction that is perpendicular to a plane of the layer.

Example 11. A method comprising: forming a structure of a monomer on a first section of a layer, wherein a second section of the layer adjacent to the first section is not covered by the structure of monomer; depositing a material on (i) the structure of monomer that is on the first section of the layer and (ii) the second section of the layer; and removing the structure of monomer and removing remnant of the material that was on the structure of monomer.

Example 12. The method of example 11, wherein the structure of monomer is removed without using a chemical etch process or photolithography.

Example 13. The method of any one of examples 11-12, wherein removing the structure of monomer comprises causing a physical change of the structure of monomer, to thereby removing the structure of monomer.

Example 14. The method of any one of examples 11-13, wherein removing the structure of monomer comprises evaporating and/or sublimating the structure of monomer.

Example 15. The method of any one of examples 11-14, wherein the material remains on the second section of the layer.

Example 16. The method of any one of examples 11-15, wherein the material is a dielectric material or a conductive material.

Example 17. A method comprising: forming a structure of a sacrificial material on a first section of a layer, wherein a second section of the layer adjacent to the first section is not covered by the structure of sacrificial material; depositing a first material on (i) the structure of sacrificial material and (ii) the second section of the layer; and removing the structure of sacrificial material by causing a physical change to the structure of sacrificial material, and removing portions of the second material that was on the structure of sacrificial material.

Example 18. The method of example 17, wherein causing the physical change to the structure of sacrificial material comprises: evaporating and/or sublimating the structure of sacrificial material.

Example 19. The method of any one of examples 17-18, wherein removing portions of the second material that was on the structure of sacrificial material comprises: removing, using compressed gas, portions of the second material that was on the structure of sacrificial material.

Example 20. The method of any one of examples 17-19, wherein the sacrificial material comprises a monomer.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future-filed applications claiming priority to this application may claim the disclosed subject matter in a different manner and generally may include any set of one or more limitations as variously disclosed or otherwise demonstrated herein.

What is claimed is:

1. A method comprising:
forming a plurality of islands of first material on a plurality of first sections of a layer, wherein a plurality of second sections of the layer are not covered by the first material;
depositing a second material on (i) the plurality of islands of first material and (ii) the plurality of second sections of the layer that are not covered by the plurality of islands of first material; and
evaporating and/or sublimating the plurality of islands of first material and removing remnants of the second material that were on the plurality of islands of the first material, such that the second material remains on the plurality of second sections of the layer, to thereby form a pattern of the second material on the layer.

2. The method of claim 1, wherein the first material is a monomer.

3. The method of claim 1, wherein removing the remnants of the second material that were on the plurality of islands of the first material comprises:
removing the remnants of the second material using compressed gas.

4. The method of claim 1, wherein forming the plurality of islands of first material on the plurality of first sections of the layer comprises:
depositing the first material on the plurality of first sections and the plurality of second sections of the layer; and
selectively removing the first material from the plurality of second sections of the layer, such that the first material remains on the plurality of first sections of the layer to thereby form the plurality of islands of first material.

5. The method of claim 4, wherein selectively removing the first material from the plurality of second sections of the layer comprises:
ablating the first material from the plurality of second sections of the layer, by passing a laser beam on at least portions of the first material that are on the plurality of second sections of the layer.

6. The method of claim 1, wherein forming the plurality of islands of first material on the plurality of first sections of the layer comprises:
depositing the first material on the layer through a mask, such that the first material is deposited on the plurality of first sections of the layer, without being deposited on the plurality of second sections of the layer; and
removing the mask.

7. The method of claim 6, wherein the mask is a shadow mask.

8. The method of claim 1, wherein evaporating and/or sublimating the plurality of islands of first material comprises evaporating and/or sublimating the plurality of islands of first material at a temperature that is at most 500° C.

9. The method of claim 1, wherein evaporating and/or sublimating the plurality of islands of first material comprises evaporating and/or sublimating the plurality of islands of first material under an at least partial vacuum environment.

10. The method of claim 1, wherein a thickness of at least one island of the plurality of islands of first material is at least 20% more than a thickness of the second material deposited on at least one of the plurality of second sections of the layer, wherein the thicknesses are measured in a direction that is perpendicular to a plane of the layer.

11. A method comprising:
forming a structure of a monomer on a first section of a layer, wherein a second section of the layer adjacent to the first section is not covered by the structure of monomer;
depositing a material on (i) the structure of monomer that is on the first section of the layer and (ii) the second section of the layer; and
removing the structure of monomer and removing remnant of the material that was on the structure of monomer.

12. The method of claim 11, wherein the structure of monomer is removed without using a chemical etch process or photolithography.

13. The method of claim 11, wherein removing the structure of monomer comprises causing a physical change of the structure of monomer, to thereby removing the structure of monomer.

14. The method of claim 11, wherein removing the structure of monomer comprises evaporating and/or sublimating the structure of monomer.

15. The method of claim 11, wherein the material remains on the second section of the layer.

16. The method of claim 11, wherein the material is a dielectric material or a conductive material.

17. A method comprising:
forming a structure of a sacrificial material on a first section of a layer, wherein a second section of the layer adjacent to the first section is not covered by the structure of sacrificial material;
depositing a first material on (i) the structure of sacrificial material and (ii) the second section of the layer; and
removing the structure of sacrificial material by causing a physical change to the structure of sacrificial material, and removing portions of the second material that was on the structure of sacrificial material.

18. The method of claim 17, wherein causing the physical change to the structure of sacrificial material comprises:
evaporating and/or sublimating the structure of sacrificial material.

19. The method of claim 17, wherein removing portions of the second material that was on the structure of sacrificial material comprises:
removing, using compressed gas, portions of the second material that was on the structure of sacrificial material.

20. The method of claim 17, wherein the sacrificial material comprises a monomer.
